(19) United States
(12) Patent Application Publication
(10) Pub. No.: US 2022/0335097 A1
(43) Pub. Date: Oct. 20, 2022

(54) ONLINE PLATFORM FOR DESIGN, CREATION, MAINTENANCE, AND INFORMATION SHARING OF A GARDEN

(71) Applicants: ESTEBAN A. CARABALLOSO, MEDIA, PA (US); NICHOLAS B. LAWING, MEDIA, PA (US)

(72) Inventors: ESTEBAN A. CARABALLOSO, MEDIA, PA (US); NICHOLAS B. LAWING, MEDIA, PA (US)

(21) Appl. No.: 17/731,343

(22) Filed: Apr. 28, 2022

Related U.S. Application Data
(63) Continuation of application No. 16/504,101, filed on Jul. 5, 2019.
Application No. 16/504,101 is a continuation of application No. 14/214,982, filed on Mar. 16, 2014, now abandoned.
(60) Provisional application No. 61/786,639, filed on Mar. 15, 2013.

(51) Int. Cl. G06F 16/9535; G06F 16/432; G06F 30/13

(52) U.S. Cl. CPC G06F 16/9535; G06F 16/434; G06F 30/13

(57) ABSTRACT

An online platform for the design, creation, maintenance, and information sharing of a garden by one or more users. A user interface receives from the one or more users of the platform ecological, botanical, environmental and/or geographical information for the design, creation, maintenance and information sharing of a garden. A database of garden knowledge is generated using the information from the one or more users received by the user interface. The database of garden knowledge is a centralized database of gardening information, including garden data and garden tasks, that is accessible and shared by and between the one or more users and that is dynamically modifiable and maintained by the one or more users via the user interface. The online platform is an online environment where the one or more users communicate and collaborate together via the user interface to maintain and share the gardening information in the centralized database.

### RELATED APPLICATION

This application is a continuation of U.S. patent application Ser. No. 16/504,101, filed Jul. 5, 2019, which is a continuation of U.S. application Ser. No. 14/214,982, filed Mar. 16, 2014, which claims benefit of U.S. Provisional Application No. 61/786,639, filed on Mar. 15, 2013.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### BACKGROUND

### Technical Field

The present disclosure is directed to online platforms, and particularly to online platforms relating to gardening.

### Background Information

There are many gardening websites on the web. These sites will typically give information on plants, when to water and how much, and other information typically drawn from books and gardening related materials.

These sites are not particularly user friendly, or at least not garden-creation friendly.

It is desirable for users to be able to have access to online platform tools that make garden creation user friendly, fun to use, and feature-rich.

### SUMMARY

The present disclosure describes an online platform for the design, creation, maintenance, and information sharing of a garden (garden platform).

The online platform is an online environment where users (gardeners) go to plan, create, grow and/or share gardens with other members. A set of garden specific feature tools track and organize the garden. The term “user” or “users” may refer to members of an online community, wherein one particular user may have access to more features and privileges than another particular user, as is known in the art.

A feature of the online platform is an encyclopedia of plant knowledge that provides members with information on when (and how) to maintain plants in one's garden. In one scenario, the information is geographically and environmentally relevant.

In a further scenario, a calendar of gardening tasks is automatically generated from the list of plants selected to grow. Based on the selection of plants identified by a user, the online platform will return a set of gardening selections, instructions, or guidelines as best gardening practices to follow. The garden user interface digitally represents the physical layout of the garden, allowing for easy planning.

In yet a further scenario, the online platform is made interactive, or otherwise social community based, with other users being able to answer questions, and/or contribute gardening tips.

In another scenario, a plant identification search module or tool is provided. This module allows the uploading of images, which are scanned, and compared against other images in a database to help the member identify the variety in question. In another scenario, the plant identification tool is dynamically interactive with the user where the tool poses questions to the user in order to identify a plant in the database. The questions posed to the user can be of multiple choice images, yes or no and text.

Once identified, more detailed information is made available via a plant encyclopedia database link. An easy-to-navigate user interface is provided for this purpose.

The summary is neither intended nor should it be construed as being representative of the full extent and scope of the present disclosure, which these and additional aspects will become more readily apparent from the detailed description, particularly when taken together with the appended drawings.

### BRIEF DESCRIPTION OF THE DRAWINGS

FIG. 1 shows an online platform for design, creation, maintenance, and information sharing of a garden (“garden platform”) in accordance with the present invention.

FIG. 2 shows a high level functional representation of garden platform web server and sub-processes in accordance with the present invention.

FIG. 3 is a high level operational flow diagram of a sub-process to create new garden, describe existing garden, or import garden from prior year.

FIG. 4 is a high level operational flow diagram of a sub-process to add to plant database in accordance with a preferred embodiment.

FIG. 5 shows how watering needs of a plant is calculated in accordance with the present invention.

FIG. 6 shows a display user interface (UI) of the Great Web Garden Share (GWGS) garden platform search functionality in accordance with the present invention.

FIG. 7 shows a display user interface (UI) of the Great Web Garden Share (GWGS) view gardens sub-process in accordance with a preferred embodiment.

FIG. 8 shows an aspect of display user interface (UI) of the Great Web Garden Share (GWGS) create garden sub-process.

FIG. 9 shows another aspect of display user interface (UI) of the Great Web Garden Share (GWGS) modify gardens sub-process in accordance with the present embodiment.

FIG. 10 shows another aspect of display user interface (UI) of the Great Web Garden Share (GWGS) modify gardens sub-process.

FIG. 11 shows another aspect of display user interface (UI) of the Great Web Garden Share (GWGS) modify gardens sub-process.

FIG. 12 shows another aspect of display user interface (UI) of the Great Web Garden Share (GWGS) search for plants and search for gardens sub-processes.

FIG. 13 shows similar types of flower forms and arrangements that may be included in search for plants sub-process.

FIG. 14 shows similar types of plant inflorenscences.

FIG. 15 shows plants with similar leaf margins, lobing, and veining.

FIG. 16 shows plants with similar leaf shapes.

FIG. 17 shows various plant leaf surfaces.

FIG. 18 shows plant leaf silhouettes.

FIG. 19 shows specific properties of plant information contained within a specific plant record in The Plant Book, the proper name given to GWGS plant database.

FIG. 20 shows additional specific properties of plant information contained within a specific plant record in The Plant Book, the proper name given to GWGS plant database.

FIG. 21 shows additional specific properties of plant information contained within a specific plant record in The Plant Book, the proper name given to GWGS plant database.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

The detailed description set forth below in connection with the appended drawings is intended as a description of exemplary embodiments of the present invention and is not intended to represent the only embodiments in which the present invention can be practiced. The detailed description includes specific details for the purpose of providing a thorough understanding of the exemplary embodiments of the invention. It will be apparent to those skilled in the art that the exemplary embodiments of the invention may be practiced without these specific details. In some instances, well known structures and devices are shown in block diagram form in order to avoid obscuring the novelty of the exemplary embodiments presented herein. The terms “online,” “internet,” and “World Wide Web” are used interchangeably as is known in the art. The term “garden” may represent any live plant or plurality of plants in that share a common area as is known in the art. Plants include annuals and perennials, including, but not limited to, trees, shrubs, bushes, flowers, vegetables as is known in the art.

The present disclosure describes an online platform for the design, creation, maintenance, and sharing of information of a garden or a plurality of gardens (hereinafter “platform” or “garden platform”).

A feature of the garden platform is an encyclopedia of plant knowledge that provides users with information on when (and how) to maintain plants in one's garden. In one scenario, the information is geographically and environmentally relevant.

In a further scenario, a calendar of gardening tasks is automatically generated from the list of plants selected to grow. Based on the selection of plants identified by a user, the tool will return a set of instructions or guidelines as best gardening practices to follow.

In yet a further scenario, the platform is made interactive, or otherwise social community based, with other users being able to answer questions, and/or contribute gardening tips.

In another scenario, a plant identification search module or tool is provided. This module allows the uploading of images, which are scanned, and compared against other images in a database to help the member identify the variety in question. In another scenario, the plant identification sub-process is dynamically interactive with the user where the tool poses questions to the user in order to identify a plant in the database. The questions posed to the user can be of multiple choice images, yes or no and text.

Once identified, more detailed information is made available via a plant database link. An easy-to-navigate user interface is provided for this purpose.

One of the major problems which need solving is the need for an integrated online gardening community where users can maintain their gardens, keep records of the tasks performed and collaborate with other gardeners in real time. In accordance with the present invention, this can be accomplished in the form of an online forum where gardeners are able to keep a record of their progress at every stage of gardening, learn and trade with other users.

A necessary feature for this kind of collaborative effort is a centralized database for gardening information. The centralized database must be available to all users and be dynamically modifiable. One embodiment might be for a user to have the ability to request new plants be added to the plant database. Another embodiment may be for the plant encyclopedia to be of the form of an online wild. Another feature is the ability for integrated electronic reminders to be sent to the users regarding when to perform gardening tasks based on a user's local weather and or other user defined criteria such as an editable list of plants which currently exist in their gardens or a list of desired plants for their garden. The centralized encyclopedia can also serve as the reservoir for detailed plant care information, such as the required hours of light a plant may need per day. This and similar information can be used to define detailed reminders which can be sent to the user, based on the plants which they have on their individual garden plant lists.

The garden platform according to the present invention provides the ability to post listings for the sale of goods and services related to gardening including the plants themselves. This is in addition to being able to perform a visual search which allows the user to identify plants using image based or geometry based botanical properties.

The problem with most gardening websites available today is that they do not offer a feature rich platform that allows for (i) donation of goods and services to a second party or user; (ii) a digital reservoir of user and administrator created garden knowledge, including a plant encyclopedia which is dynamically maintained containing plant facts, plant requirements, important times of year, how to tend information and other digital content including videos, pictured and posted user comments and blogs; (iii) communicating and collaborating on garden tasks, e.g., sharing a calendar and email system as well as planning and task sharing and service bartering; (iv) exchanging and trading goods and services directly for goods and services without the need for currency (futures contracts); creating a digital representation of the plants a user may have in their garden; (v) automatically populating a calendar with gardening tasks based on plants which a user has in their digital garden; (vi) sending reminders of scheduled garden tasks to other users and themselves; (vii) user posting of goods and services for sale and trade; (viii) users negotiating exchanges of goods and services; (ix) performing plant identification searches by using geometry-based botanical properties in a visual searches for any plant in the database using a subtractive or exclusionary algorithm; (x) adding or requesting of new varieties by a member to an administrator so as to enhance plant database; and/or (xi) integrated user-location based weather feed that sends users weather based alerts e.g., to alert to increase (decrease) watering period or frequency during expected dry (wet) weather conditions.

One of the reasons plants don't survive or grow poorly is because they outgrow their space. The garden platform according to the present invention includes features that provide guidance regarding optimum space conditions for any selected plant. In another scenario, the user describes the environment he/she has to work with, including location, sun/shade conditions, physical constraints, etc. and the platform provides a selection of plants, along with images and descriptions, to suit those conditions. In another scenario, the platform considers or recommends, if necessary, optimum soil conditions, as well as information as to compatibility between selected varieties if sharing soil, for example.

Once the garden bed is established, the platform includes a personalized garden assistant module. The module provides assistance on when to plant seeds, trim roses, harvest fruits, and the like.

In another scenario, the platform provides personalized gardening task feedback. Based on the selected garden plants, an alert feature lets the member know the optimal time to trim the roses, send a reminder about doing so, potentially including a how-to video along with additional information.

The alert feature further includes interactivity with other members. In one scenario, users can group to form a “garden Pool” to help spread gardening work. Even small gardens can require a high level of attention. With customized alerts and platform community gardening, responsibility can be shared among neighbors in a way where each works together for the common aesthetic and agricultural benefit of the whole group.

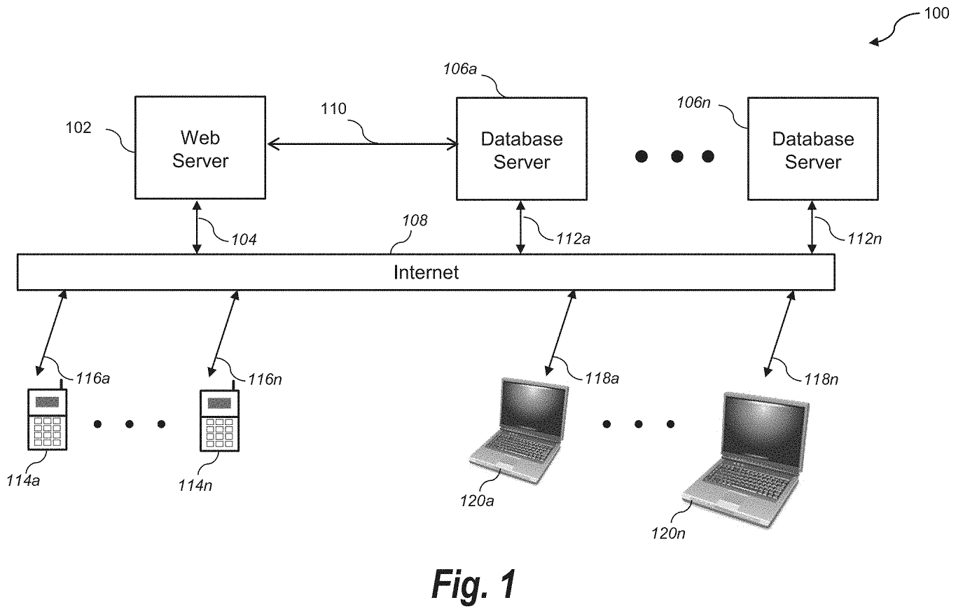

FIG. 1 shows online platform 100 for design, creation, maintenance, and information sharing of a garden (“garden platform”) in accordance with the present invention. Web server 102 is coupled to Internet 108 through connection 104. The components that comprise Web server 102 and connection 104 are well known in the art. Web server 102 delivers content through the World Wide Web to at least one of portable computing devices 114a, . . . , 114n or non-portable computing devices 120a, . . . , 120n. Information displayed on portable computing devices 114a, . . . , 114n and non-portable computing devices 120a, . . . , 120n may also refer to “client side” interactions as is known in the art. Connection methods 116a, . . . , 116n which couple portable computing devices 114a, . . . , 114n to Internet 108 may be wireless or wired. Examples of wireless connection methods 116a, . . . , 116n are cellular connections implementing wireless standards such as LTE or 3GPP and other wireless connections such as Bluetooth and Wifi as is known in the art. Examples of wired connection methods 116a, . . . , 116n are universal serial bus (USB). Similarly, connection methods 118a, . . . , 118n may be wireless or wired. Connection methods 118a, . . . , 118n may use additional technologies, for example, Ethernet, as is known in the art.

Garden platform 100 further comprises database servers 106a, . . . , 106n which are coupled to Internet 108 via connection methods 112a, . . . , 112n as is known in the art. The database servers may be co-located in the same physical location as web server 102 or may be remotely located. In one aspect of the present invention, database server 106a contains a database of digital content comprising of gardening related information including plant information including video, audio, and text. For weather information, it is convenient to use database servers from third parties such as The Weather Channel etc., as is known in the art. In another aspect, web server 102 may be coupled to database servers 106a, . . . , 106n via alternate network connection 110. Alternate connection 110 may be used when database server 106a is co-located with web server 102. An example of alternate connection 110 is an Ethernet connection through a router. Great Web Garden Share (GWGS) is a commercial instantiation and demonstration of garden platform 100.

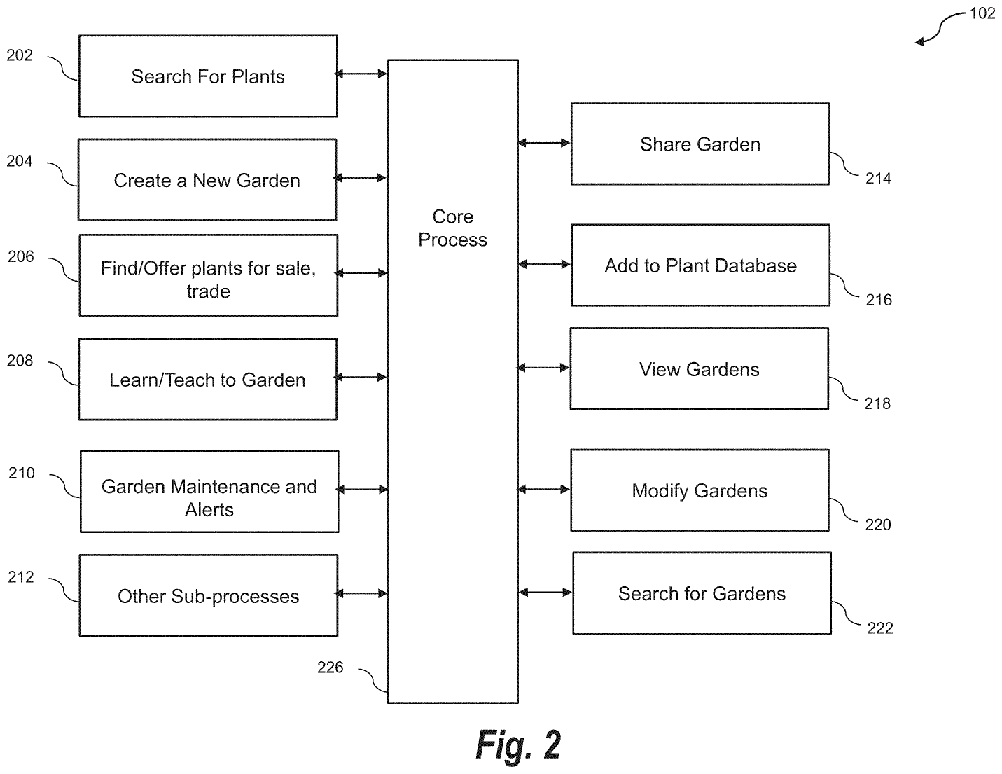

FIG. 2 shows a high level functional representation of garden platform web server 102 and sub-processes in accordance with the present invention. Core process 226 implements garden platform web server 102 functionality and serves content to computing devices as noted above. Core process 226 is coupled to sub-processes through methods known in the art. Sub-processes may consist of subroutines of machine readable code that implement specific functions in a real-time or non real-time manner. Sub-processes may also operate on other web servers and are coupled to core process 226 through methods mentioned above.

Sub-process 202 implements the search for plants functionality of garden platform 100. A graphical user interface (UI) enables searching for a plant by uploaded or stored images which is a valuable feature, especially if a garden exists with plants that are of unknown origin or unidentified plants. Furthermore, sub-process 202 enables searching for a plant by name, type of plant, genus, species, climate type, leaf type, water needs, light needs, difficulty of care, and additional plant properties that are known in the art.

Sub-process 204 implements the create a new garden functionality of garden platform 100. A graphical user interface (UI) enables the creation of a new garden which configured. More detail on sub-process 204 is given below.

Sub-process 206 implements the ability to seek out plants from other users that may be for sale, or plants that may be for trade. The ability to offer plants for sale and trade is also implemented by sub-process 206. Methods for searching and completing purchases, sales, and trades are well known in the art with websites such as eBAY, Craigslist, Facebook etc.

Sub-process 208 implements the learn or teach to garden module. Video, audio, and textual informational archives may be presented to facilitate the learning of gardening, as is known in the art.

Sub-process 210 implements the garden maintenance and alerts functionality. This sub-process may include a calendar and may combine at least one of an alert to perform some type of maintenance. Example alerts may be to water the garden due to extreme weather conditions or to cover the garden when the outside air temperature is too cold. More information on sub-process 210 is provided below.

Sub-process 214 enables the sharing of a garden and garden data with another user or a plurality of users of garden platform 100. When a garden is shared, an alert from sub-process 210 may be created to notify the user or users that a garden has been shared. Hyperlinks may be provided in the alert to easily allow a user access to a garden that has been shared with them. Methods of information sharing are known in the art in many online communities such as Linkedin, Facebook, and others.

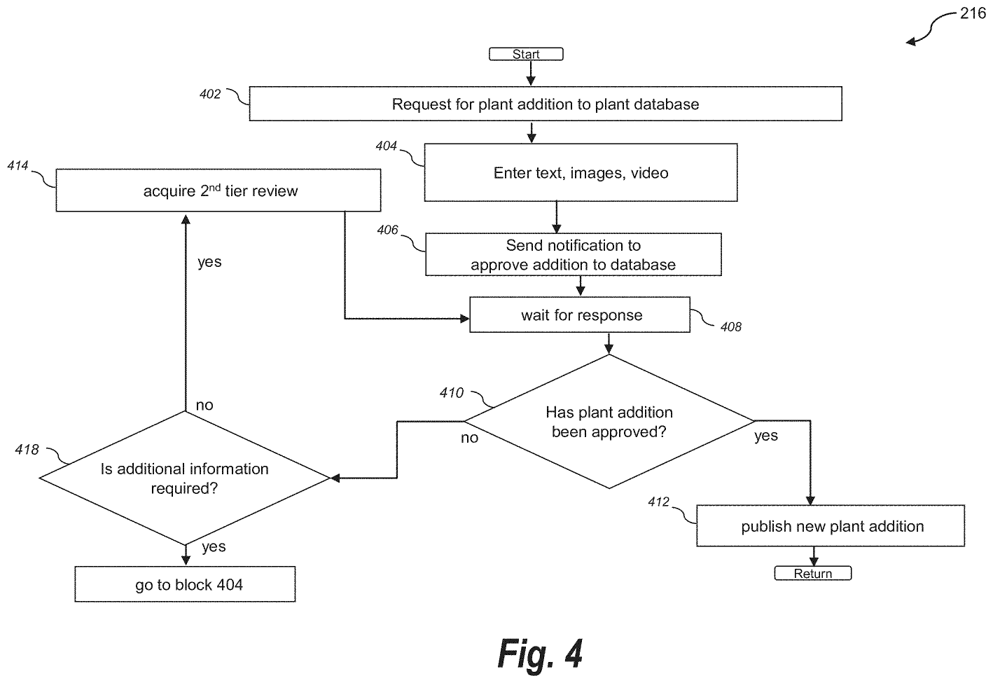

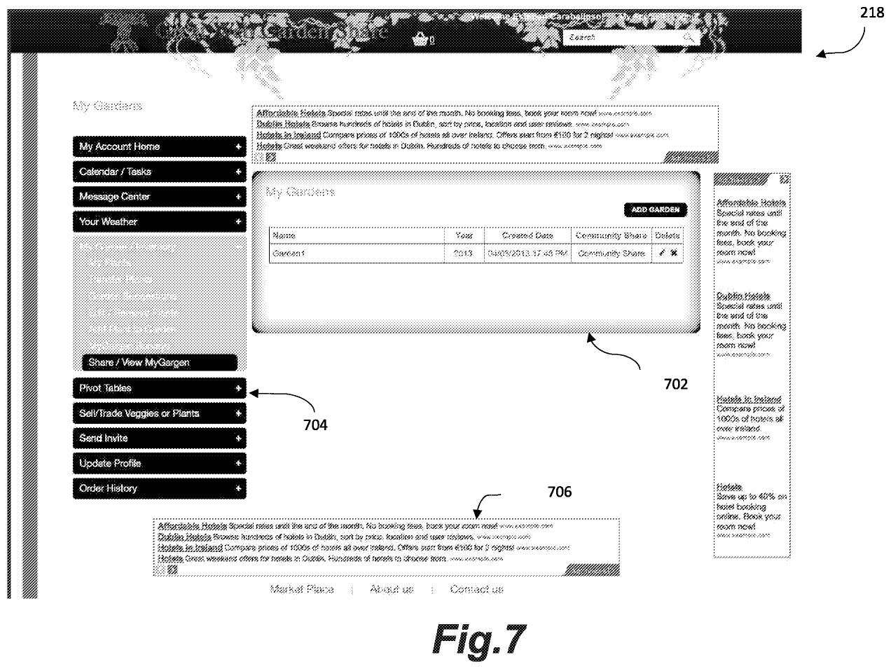

Sub-process 216 enables the addition of plant information to a database. FIG. 4 describes a high level operational diagram of the add to plant database functionality. Sub-process 218 is the view gardens process wherein garden platform 100 UI shows an example of the existing gardens that have been created for a particular user as depicted in FIG. 7. Alerts can be constructed by multiple methods. When a user defines a plant which is added to their on-line garden they will automatically be able to access information on when to perform certain gardening tasks associated to the plant which they are selected from the list. This information is automatically presented to the user and the offer is made to remind the user of when to perform these tasks

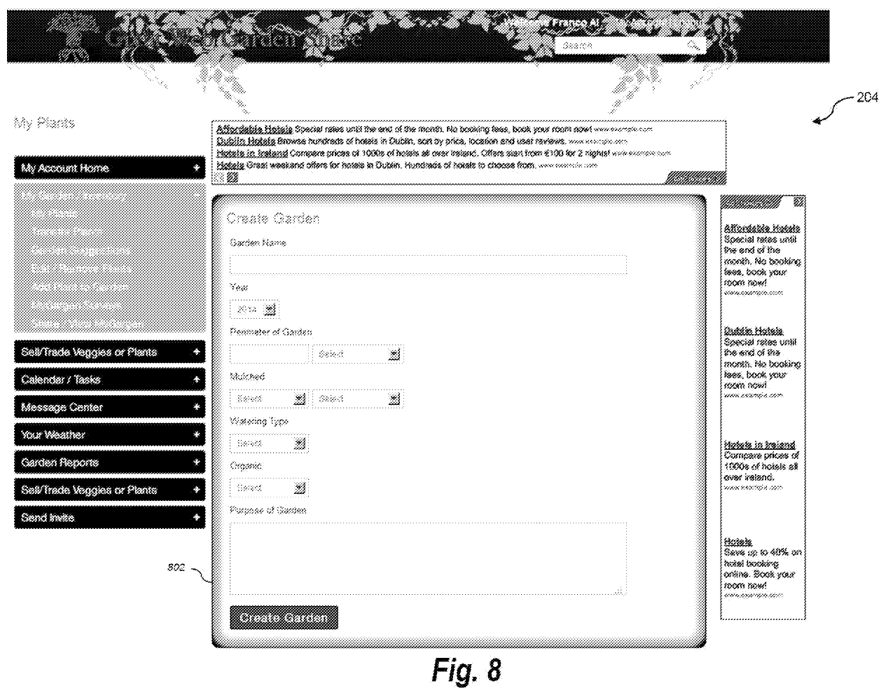

Sub-process 220 enables the user to select, modify, and alter their garden. A graphical UI is presented to facilitate the modification process. Some examples of the graphical UI to modify a garden is depicted in FIGS. 8-12.

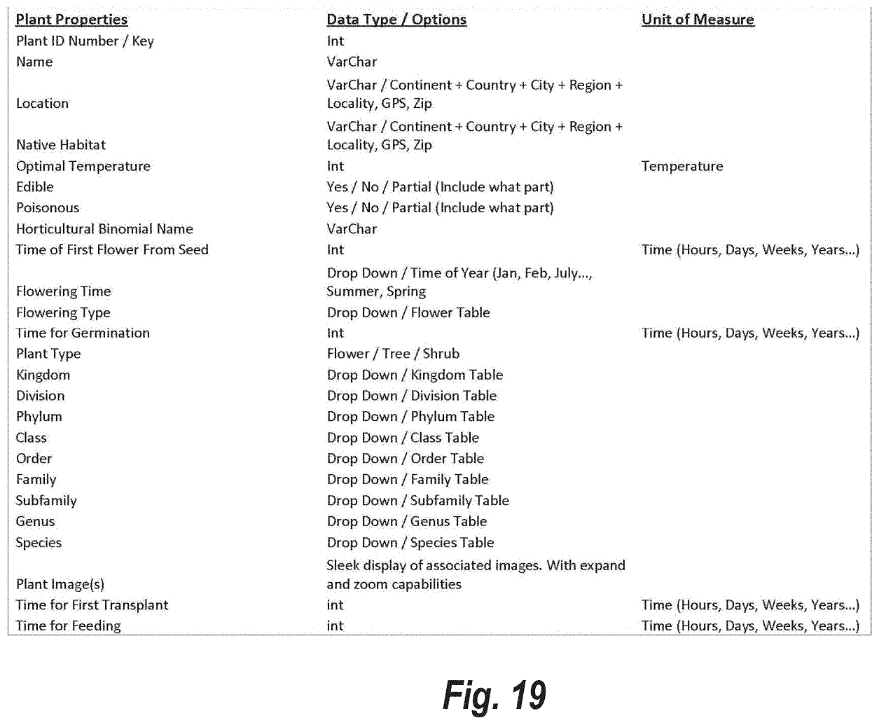

Sub-process 222 is the search for gardens feature wherein a user can search for other users, garden types by climate, plant type, size, or other parameters as depicted in FIGS. 19-21.

Additional sub-processes 212 may be coupled to core process 226 to provide functionality that web-based users expect as is known in the art. Sub-processes 212 include, but are not limited to, user registration, registration of an advertiser, displaying of advertisements, donate money to various causes, email and messaging functionality, password protected user login, forgot password recovery, entering and editing of personal information, register as a user with increasing user privileges, starting or inviting or joining a chat session, viewing of calendar of events, adding of geolocation data, search or browse bulletin board information, comment on bulletin board, sell and buy, provide commentary, rate a buyer or seller, rate a trade, post item for trade, donate, pay a subscription fee, create or edit up-coming community events, view local weather, view historical weather trends, comment on weather, view statistical data aggregated by garden data, view tutorials, request technical support, post instructional information, view advertisement reports, upload images, pay for advertising, reset password, approve or edit bulletin board posts, view bulletin board statistics, generate backups of data or website, restore backed up data, perform platform maintenance, batch import of database data among others. These additional sub-processes are generally known in the art and are mentioned generally as features that are generally desirable among popular online platforms.

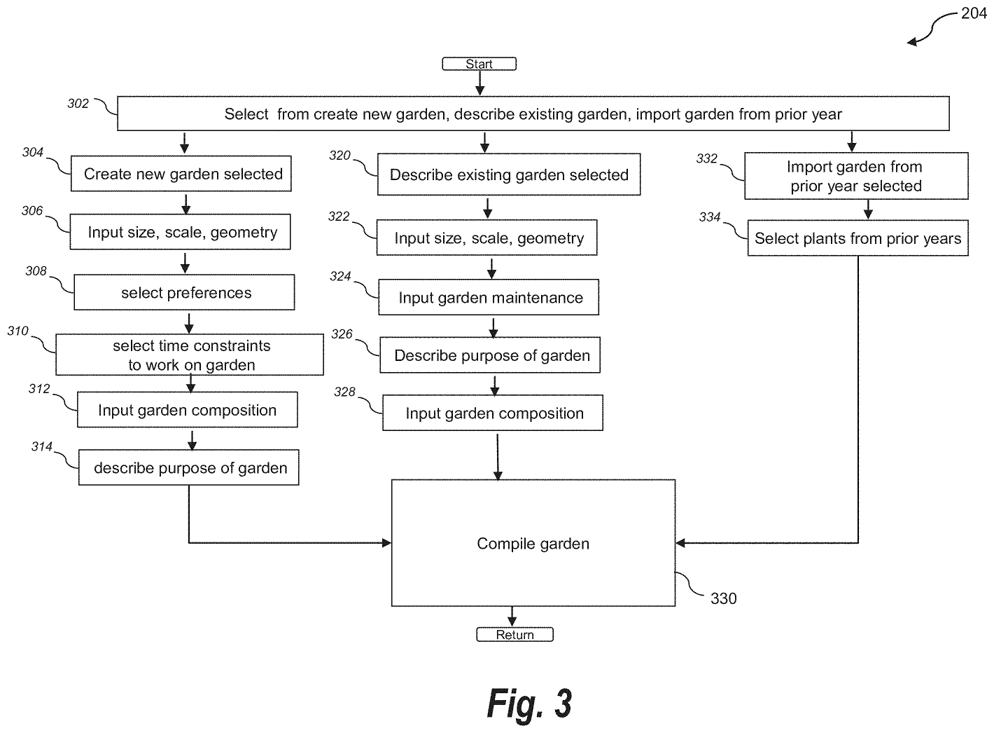

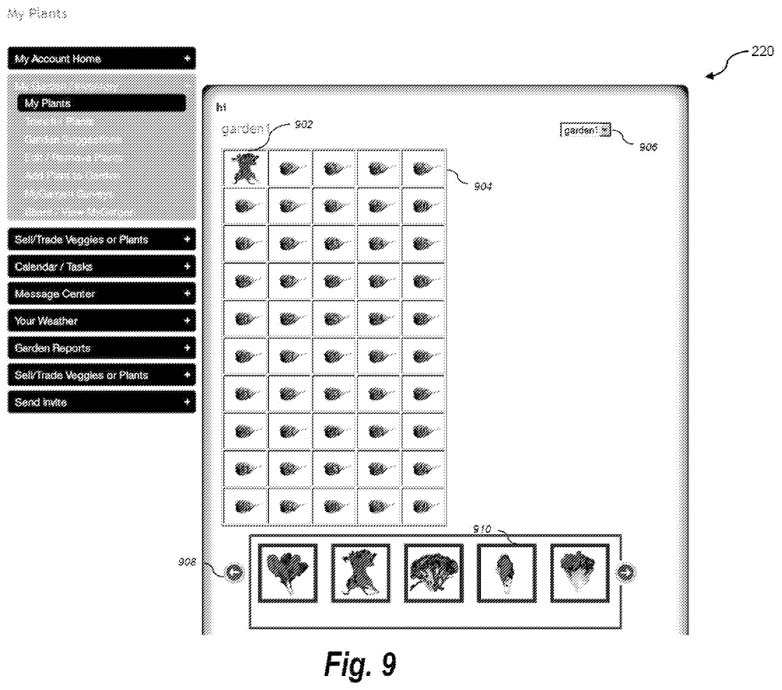

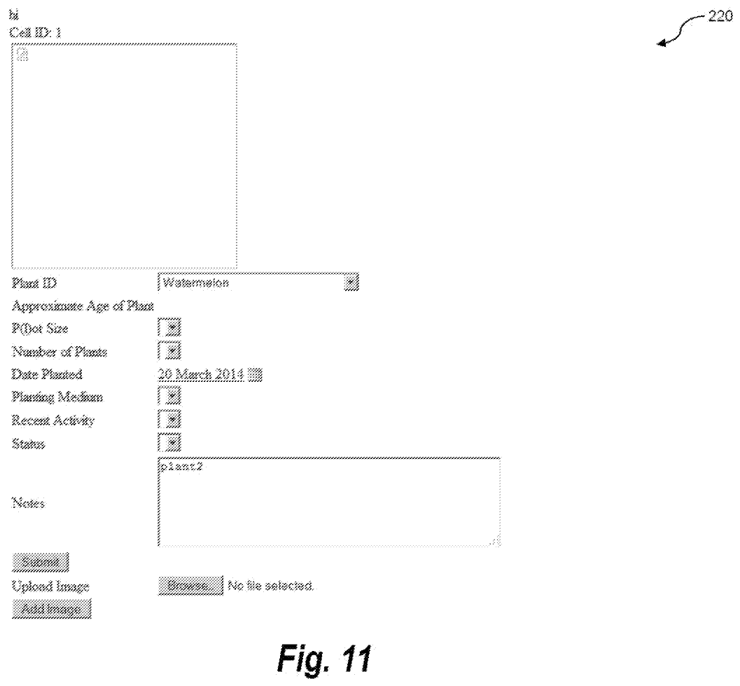

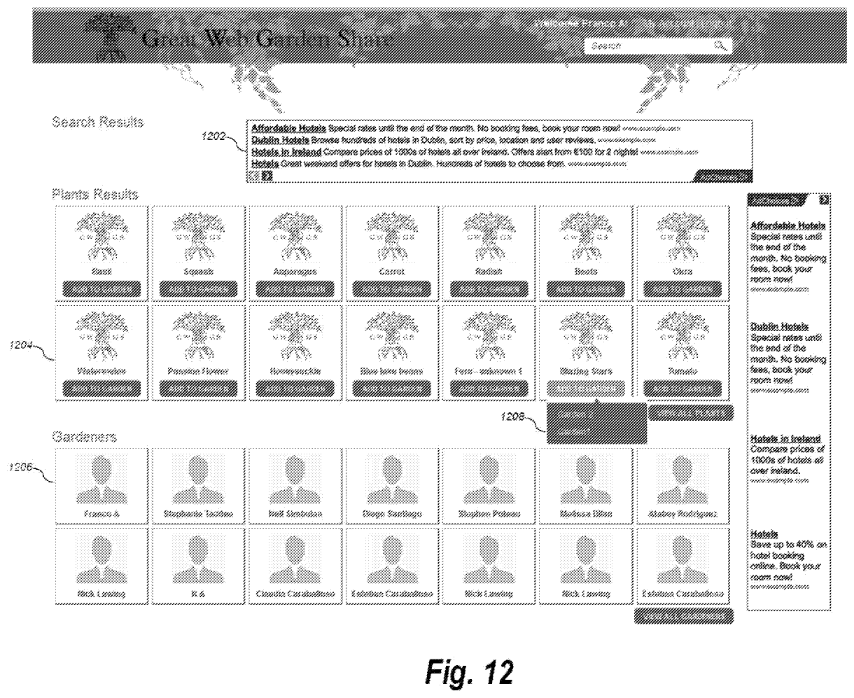

FIG. 3 is a high level operational flow diagram of a sub-process to create new garden, describe existing garden, or import garden from prior year. Flow begins at block 302 where a selection is prompted between creating a new garden, to describe an existing garden, or import a garden from a prior year. When create new garden is selected, flow is directed to block 304 to begin the new garden process. An example UI of the new garden input is depicted in FIG. 8. Flow continues to block 306 wherein the new garden attributes are collected comprising at least one of size, scale, geometry, watering methodology, soil type, and other attributes. Flow then continues to block 308 where preferences for the garden are selected such as desired color scheme, or whether the garden may comprise perennials, annuals, flowers, bushes, shrubs, or other plant types. Flow then continues to block 310 wherein the time constraints for maintaining the garden are set. These time constraints may be comprised of watering time, garden preparation time, garden setup time, and periodic maintenance time (e.g. hours per week, hours per month). Flow then continues to block 312 wherein plants to add to the garden may be selected by searching via text, or visually added through a graphical user interface, or a combination thereof. The availability of plants to be added to the garden may be limited by garden platform 100 depending at least one of time of year, geolocation, soil type and other preferences known in the art. An example reason to limit plant choices is to assist in the planting of the garden wherein selecting plants that that would not be able to live and flourish because of the ecological conditions should be avoided to not incur excessive cost or decimation of the garden. Examples of graphical user interface plant selection are displayed in FIG. 9 and FIG. 12. An example of a combination of text and graphical information selection of plants is in FIG. 11. The graphical user interface for selecting plants may also be based on the physical outlay of the garden, giving the user a desirable and valuable visual correlation between actual location of plants and the representation on garden platform 100 (known as “Wysiwyg” in the art). Once all the plants for the garden have been selected, flow continues to block 314 wherein the purpose of the garden or any additional notes may be collected. The purpose of the garden may be for food, ornamental display, erosion considerations, soil enrichment considerations, financial gain, among other purposes as known in the art. Finally, flow continues to block 330 wherein the garden is compiled, database records for the garden are updated, alerts may be configured such as watering schedule, etc.

If describe existing garden is selected in block 302, then flow continues through block 320 to block 322 wherein the physical dimensions of the existing garden are input, much in the same manner as the functionality of block 306. Flow then continues to block 324 wherein the actual garden maintenance requirements are input which may be comprised of watering time, garden preparation time, garden setup time, and periodic maintenance time (e.g. hours per week, hours per month). Flow continues to block 326 wherein the purpose of the garden is input, in the same manner as block 314. Flow then continues to block 328 wherein the existing garden composition is input using a graphical user interface, or text input, or a combination thereof in a manner similar to block 312. One difference between block 328 and block 312 may be the ability to select from a larger selection of plants, as an existing garden may have plants that are not well suited to the ecological climate that they are planted in. In this case, garden platform 100 may notify the user that plants that comprise their garden may not be suitable for their garden, given these ecological constraints. Garden maintenance and alerts 210 may be setup automatically to provide this notification of plant suitability. Finally, flow continues to block 330 wherein the garden is compiled, database records for the garden are updated, alerts may be configured such as watering schedule, etc.

If import garden from prior year is selected in block 302, flow continues through block 322 to block 334. Block 334 allows the user to select plants from a garden in a prior year to add to a new garden. Prior year garden plant selection may be comprised of a graphical user interface selection mechanism, with text selection, or via other identifiable tags such as plant number etc. Once plants from prior years are selected, flow continues to block 330 wherein the garden is compiled, database records for the garden are updated, alerts may be configured such as watering schedule, etc.

FIG. 4 is a high level operational flow diagram of sub-process 216 to add to plant database in accordance with a preferred embodiment. Flow begins at block 402 wherein a request is received by garden platform 100 to add a plant to the garden platform 100 database. A specific process is required for adding a plant to the database because it is desirable to have the most robust and accurate plant database possible that is available to users. A specific process will also ensure that incomplete, inaccurate, or otherwise erroneous information and records are created thus increasing the value of the compiled plant database. Flow continues to block 404 after the request to add a plant to the garden platform 100 database wherein information pertaining to the plant record to be added is input. The plant record information comprises at least one, but not limited to, of text, images, video, online references, or internet hyperlinks. Flow then continues to block 406 wherein garden platform 100 sends a notification to a user of web platform 100 that is authorized to approve or deny the addition of a plant record. Flow then continues to block 408 wherein a response from said authorized user is tendered and flow then continues to block 410. Block 410 checks to see if the plant record addition has been approved. If yes, then flow continues to block 412. Block 412 updates the plant database with the new plant record and publishes the record so that all general garden platform 100 users may access the new plant record. If block 410 determines that the plant record addition is denied (“no”), then flow continues to block 418. In block 418, authorized user determines whether additional information is required. There may be missing description, text, video, images or other pieces of information that may be required. If additional information is required then flow goes back to block 404 wherein the user requesting the addition of a plant record will be requested to enter additional information. If no additional information is required as determined by block 418, then flow continues to block 414. If the request for new plant record has been documented sufficiently, there may be a need by the authorized user to get a 2^{nd} tier review. The 2^{nd} tier review is conducted in block 414 wherein another authorized user is queried to authorize the addition of the new plant record. A 2^{nd} tier reviewer may have more relevant plant knowledge and expertise of the particular type of plant that is being requested to be added to the plant database. Flow then continues to block 408 wherein sub-process 216 waits for a response from said 2^{nd} tier reviewer who is an authorized user. The flow continues as before until the new plant record addition is approved and published. Note that block 410 may automatically delete the new plant record request if a predetermined number of authorized user or users denies approval of the plant record addition. This automatic deletion may also occur if the plant addition is determined to be redundant to other records in the plant database.

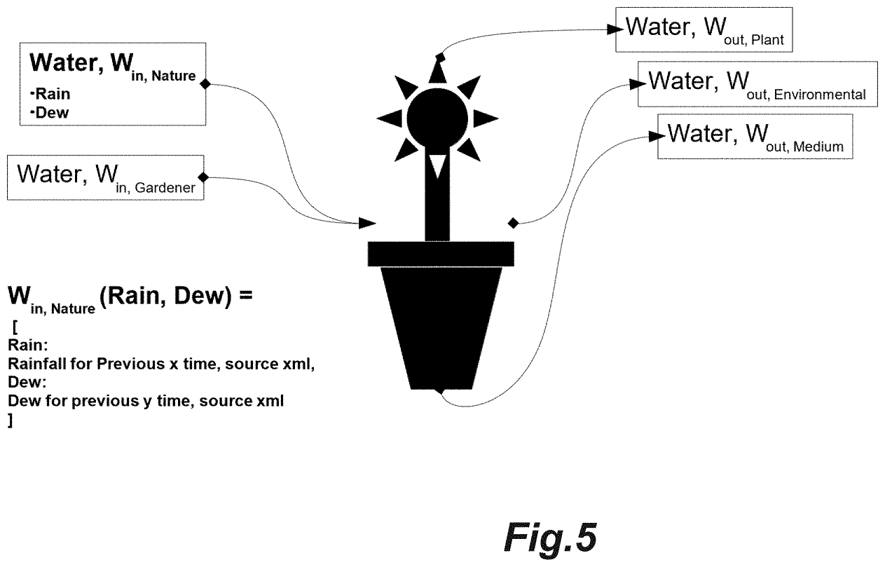

FIG. 5 shows how watering needs of a plant is calculated in accordance with the present invention, identifying W_{in,Nature}, W_{in,Gardner}, W_{out,Plant}, W_{out,Environmental}, and W_{out,Medium}. Garden maintenance and alerts 210 may use at least one of weather, geolocation, water requirements for a given plant in a user's garden, and other aspects to determine if an alert should be set. W_{in,Nature} is defined as the amount of water for a predetermined time interval that is provided naturally, usually through rain or dew formation, as is known in the art. W_{in,Gardner} is defined as the water that is provided by the gardener for a predetermined time interval, typically through manual or automatic watering systems. W_{out,Plant} is defined as the amount of water a given plant consumes during a predetermined time interval. W_{out,Environmental} is defined as the amount of water in a predetermined time interval that leaves the plant due to the environment, such as during evaporation. W_{out,Medium} is defined as the amount of water lost in a predetermined time interval due to drainage, as is known in the art. The net water is determined in accordance with the following expression:

Net water=W_{in,Nature}+W_{in,Gardner}−W_{out,Plant}−W_{out,Environmental}−W_{out,Medium}

Net water is determined over a predetermined time interval. An alert may be set by garden maintenance and alerts 210 if the net water is below a predetermined threshold. The predetermined threshold may be different for different plants. For practical implementation, water from nature may be a linear combination of actual rainfall and dew point data collected over the predetermined time interval. Water consumed by the plant or lost through environmental or medium means may be calculated to be a linear combination of humidity, temperature, measured drainage, plant growth, and aesthetic plant health as is known in the art.

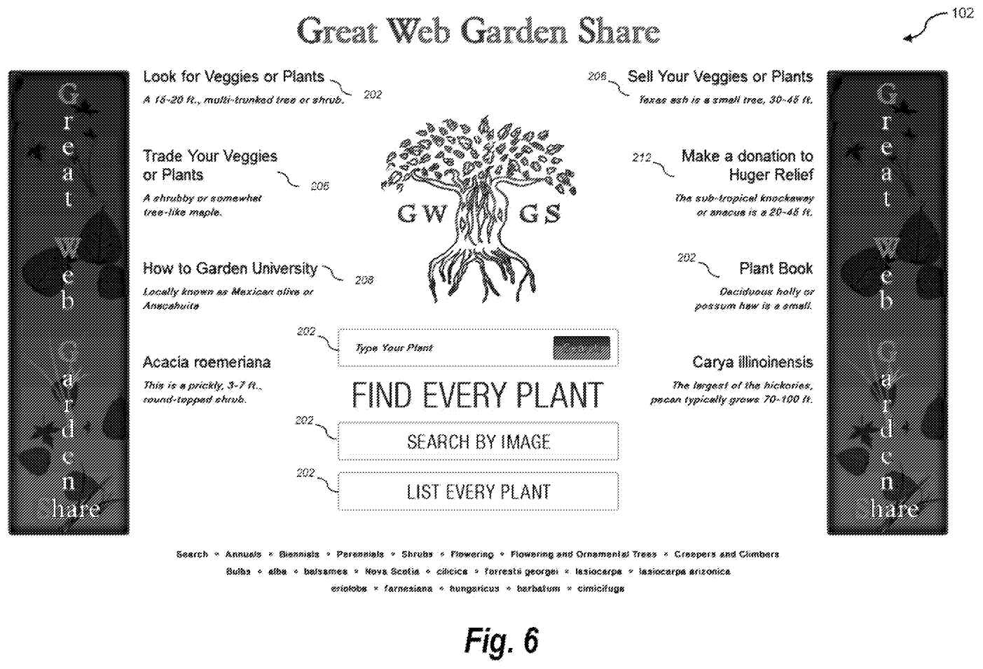

FIG. 6 shows a display user interface (UI) of the Great Web Garden Share (GWGS) garden platform 100 search functionality in accordance with the present invention. The UI is laid out in an aesthetically pleasing format with easy to access interfaces. The figure denotes sub-process elements corresponding to web server 102.

FIG. 7 shows a display user interface (UI) of the Great Web Garden Share (GWGS) view gardens sub-process 218 in accordance with a preferred embodiment. Display window 702 depicts the available gardens for a particular user. Advertisement 706 is displayed, as is known in the art. Online platform navigation bar 704 is displayed with collapsible menus, facilitating the selection of sub-processes of web server 102.

FIG. 8 shows an aspect of display user interface (UI) of the Great Web Garden Share (GWGS) create garden sub-process 204. Display window 802 depicts create garden sub-process 204 UI in accordance with the present invention.

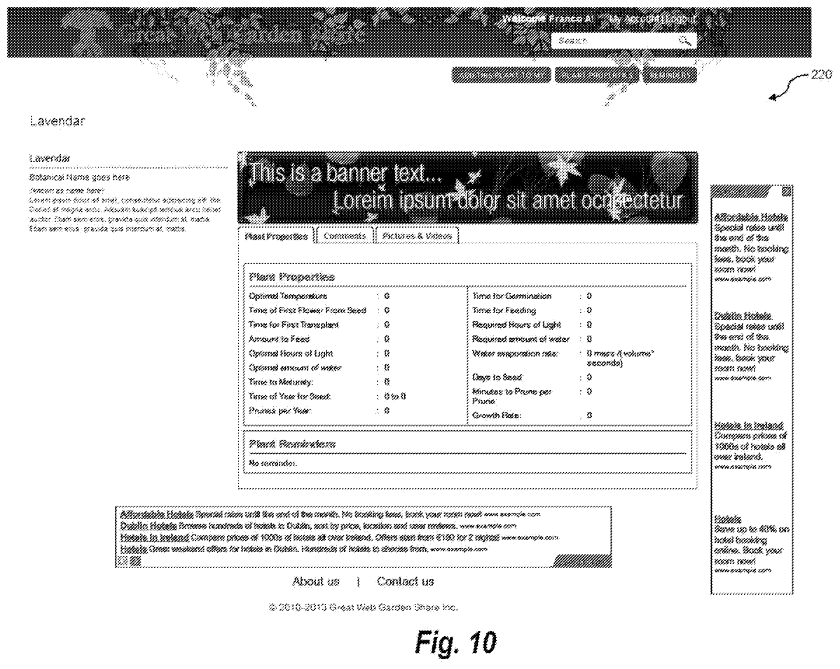

FIG. 9 shows another aspect of display user interface (UI) of the Great Web Garden Share (GWGS) modify gardens sub-process 220 in accordance with the present embodiment. The display UI for sub-process 220 is especially desirable and useful because the user can quickly ascertain the configuration of their garden. Grid 904 is a graphical representation that corresponds to the physical instantiation of a user's garden. Each element of grid 904 contains a hyperlink which enables plant information to be entered for a particular cell. Examples of a display user interface that enables configuration and plant information to be entered for a particular cell in grid 904 is depicted in FIGS. 10-12. Cell 902 is representative of all cells in grid 904. Each cell on the display represents the relative physical proximity to the actual garden (“Wysiwyg”). When a garden is created, the cells of grid 904 may have numerical representation. Upon completion of selecting the particular plant for a particular cell, an image, if available, is displayed in the corresponding cell location. For example, cell 902 was selected to contain the vegetable beets. The plant database picture for beets is displayed in cell 902. Note that cell 902 remains a hyperlink, allowing the item to be quickly edited. To facilitate population and modification of a user's garden, plant picture bar 910 is provided along with scroll capability 908. Items in plant picture bar may also be hyperlinks to additional information about that plant. A user may drag and drop an element from plant picture bar 910 into a particular cell in grid 904, wherein grid 904 will update the corresponding particular cell with the plant information that was dragged and dropped. Dragging and dropping is known in the art, but novel in combination with grid 904 corresponding to a physical representation of plants in a user's garden. Finally, pull-down menu 906 facilitates quick selection between multiple gardens that a user may have.

FIG. 10 shows another aspect of display user interface (UI) of the Great Web Garden Share (GWGS) modify gardens sub-process 220. When a cell in grid 904 is clicked, the particular plant summary is displayed. Key plant data such as optimal temperature, optimal light, amount to feed, required water, among other plant aspects known in the art may be displayed. Plant reminders that may have been generated by garden maintenance and alerts 210 may also be displayed.

FIG. 11 shows another aspect of display user interface (UI) of the Great Web Garden Share (GWGS) modify gardens sub-process 220. This UI is useful in the case where a plant may not be in the database, or a user would like to customize some of the information such as a customized image to be used in cell 904, for example.

FIG. 12 shows another aspect of display user interface (UI) of the Great Web Garden Share (GWGS) search for plants and search for gardens sub-processes 202 and 222. Advertising 1202 is served and displayed using methods known in the art. Search plant results 1204 are displayed based upon specific search criteria. Plant results 1204 may also contain thumbnail images or other graphical depictions of plants. Plant results 1204 contain hyperlinks that allow quick addition of a plant to a user's garden. Hovering a selection pointer over the “add to garden” hyperlink in plant results 1204 allows addition of a particular plant to a specific user's garden. In another aspect, search for gardens 222 functionality includes list of other gardeners 1206. Items in list of other gardeners 1206 are hyperlinks that invoke view gardens sub-process 218 to view another gardener's garden information. List of other gardeners 1206 also provides a hyperlink to allow a user to view all possible gardeners' gardens. Only gardens that are enabled to be shared by sub-process 214 are listed in list of other gardeners 1206.

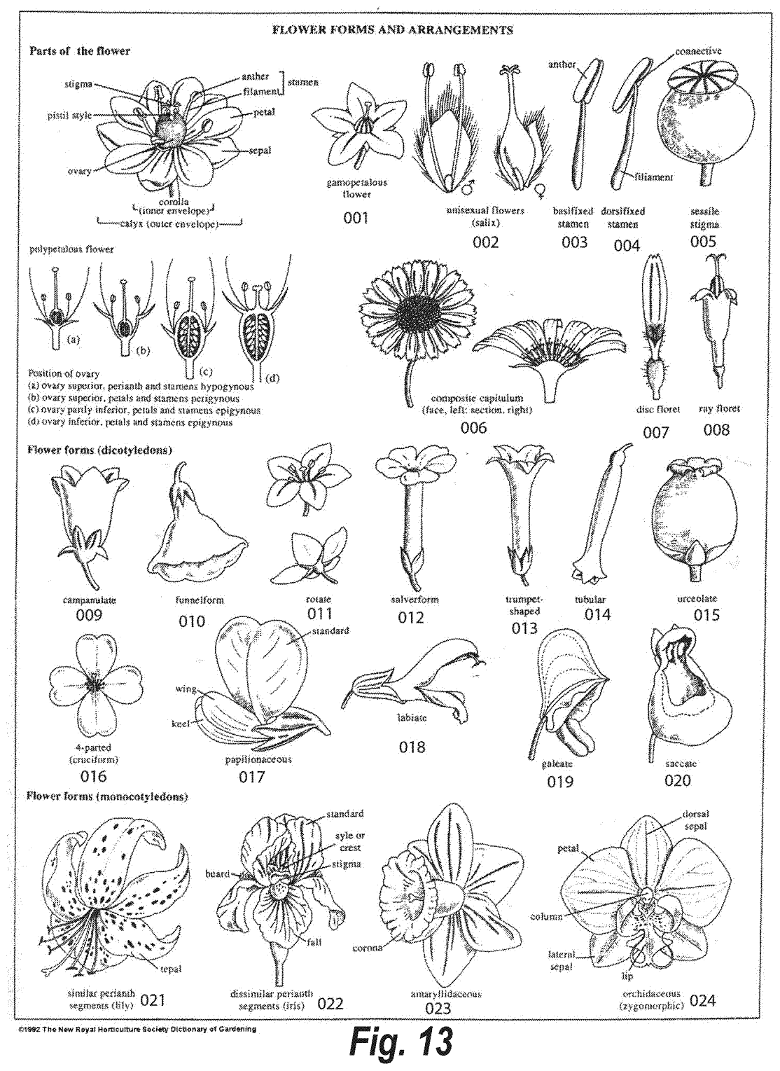

FIG. 13 shows similar types of flower forms and arrangements that may be included in search for plants sub-process 202. The ability to group flowers by similar shapes assists in the visual identification process. It is easier to identify a plant by clicking on an image the closest matches as opposed to being asked questions about flower parts that a user has no knowledge of.

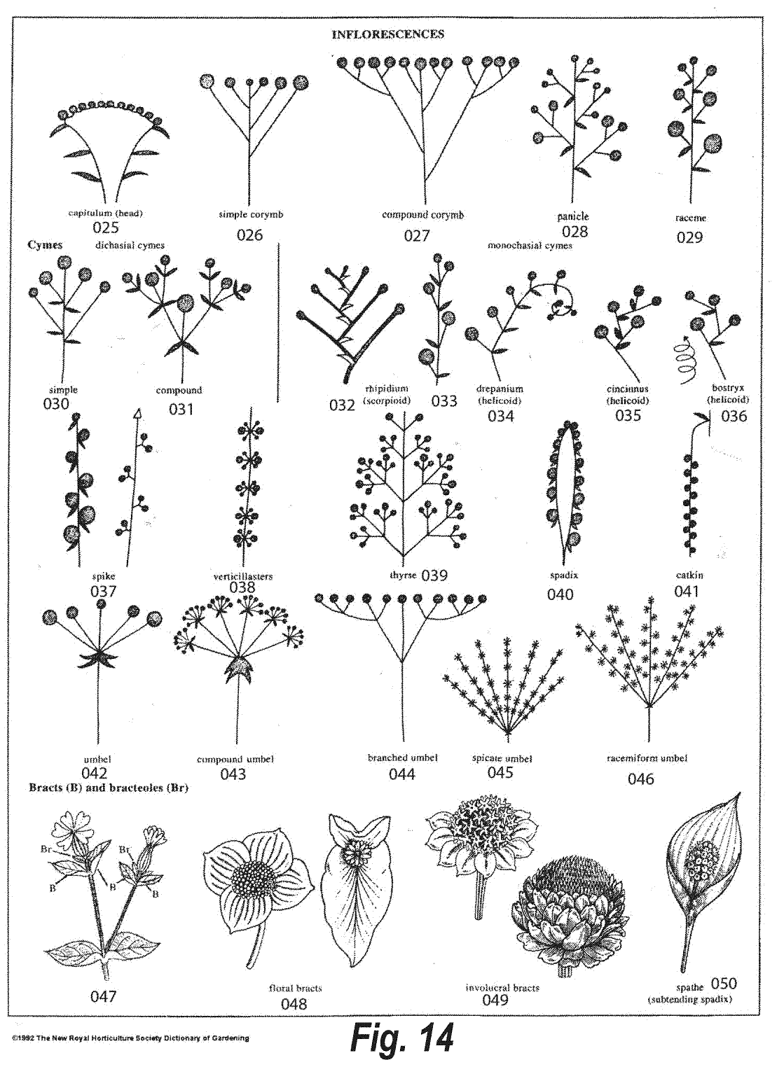

FIG. 14 shows similar types of plant inflorenscences. The ability to group plants by similar inflorenscences assists in the visual identification process. It is easier to identify a plant by click on an image that closest matches a user preference as opposed to a user being asked to describe the inflorescence.

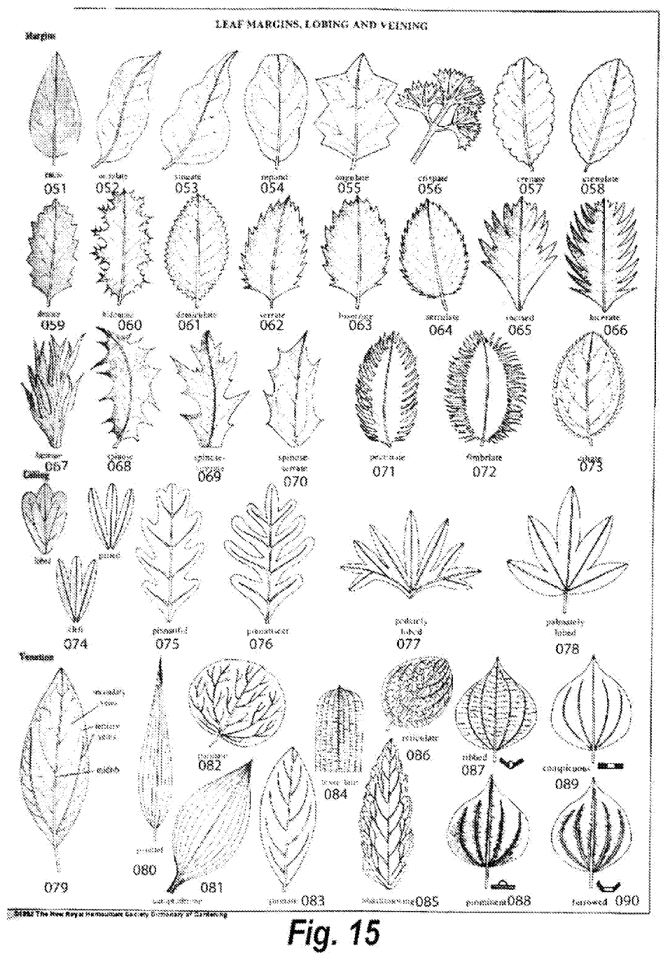

FIG. 15 shows plants with similar leaf margins, lobing, and veining. The ability to group plants by similar margins, lobing, or veining assists in the visual identification process and may be an aspect of search for plants sub-process 202. It is easier to identify a plant by clicking on an image that closest matches as opposed to a user being asked about a leaf's lobing.

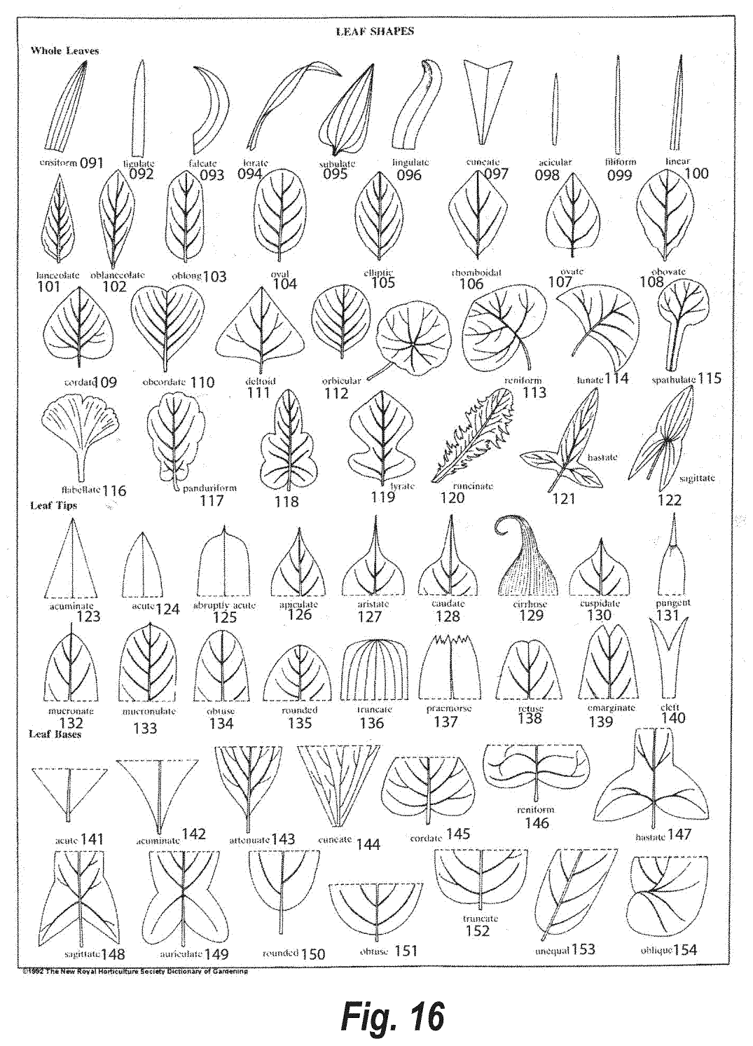

FIG. 16 shows plants with similar leaf shapes. The ability to group plants by similar leaf shapes assists in the visual identification process and may be an aspect of a visual search for plants sub-process 202. It is easier to identify a plant by clicking on an image that closest matches a user's preference as opposed to being asked about a leaf's shape.

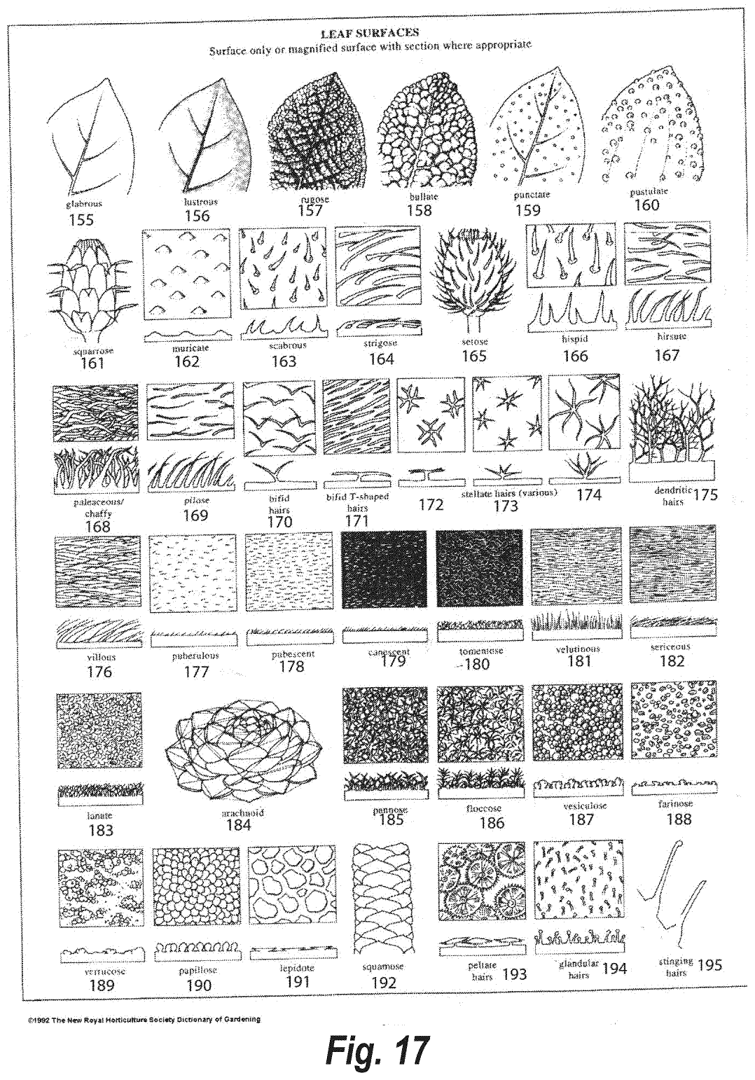

FIG. 17 shows various plant leaf surfaces. The ability to group plants by similar leaf surfaces may assist in the visual identification search for plants sub-process 202.

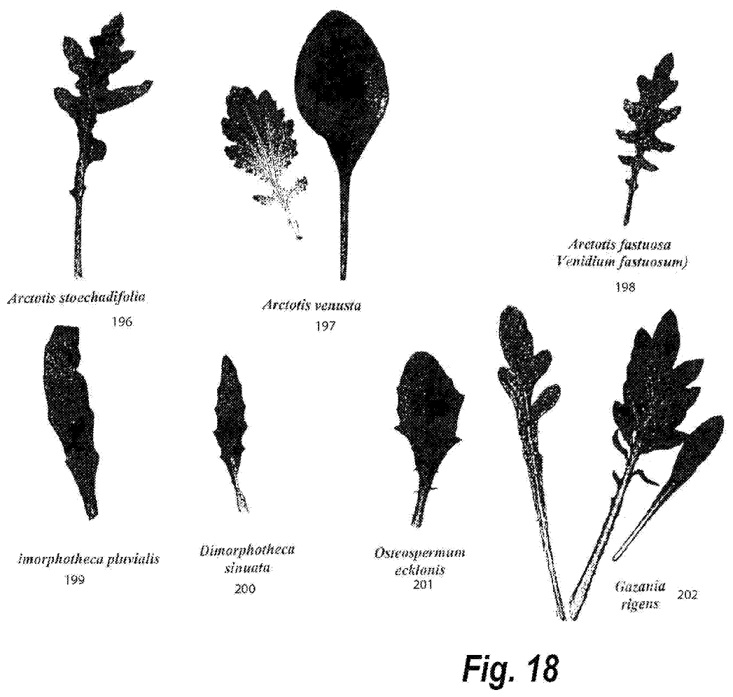

FIG. 18 shows plant leaf silhouettes. A user can easily hold a leaf up to his computer screen and compare it to a displayed leaf. These images assist in the visual identification process for search for plants sub-process 202

FIG. 19 shows specific properties of plant information contained within a specific plant record in The Plant Book, the proper name given to GWGS plant database. The Plant Book strives to obtain as much information about plants as possible. User's may request additional property fields be added through sub-process 216 as detailed above, as well as provide information to fill-in missing information. All information may be verified by an authorized user such as a professional horticulturist.

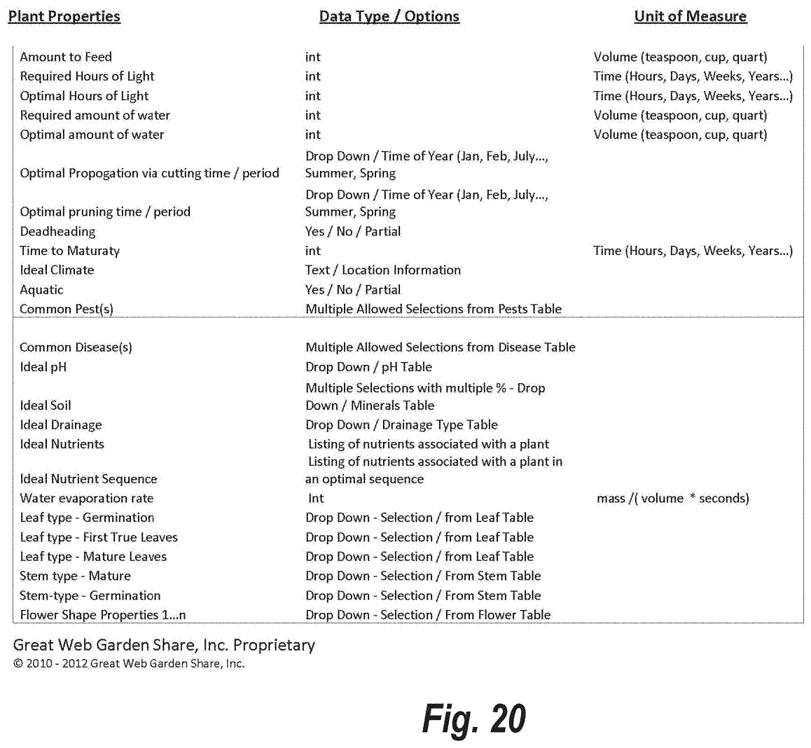

FIG. 20 shows additional specific properties of plant information contained within a specific plant record in The Plant Book, the proper name given to GWGS plant database. The Plant Book strives to obtain as much information about plants as possible. User's may request additional property fields be added through sub-process 216 as detailed above, as well as provide information to fill-in missing information. All information may be verified by an authorized user such as a professional horticulturist.

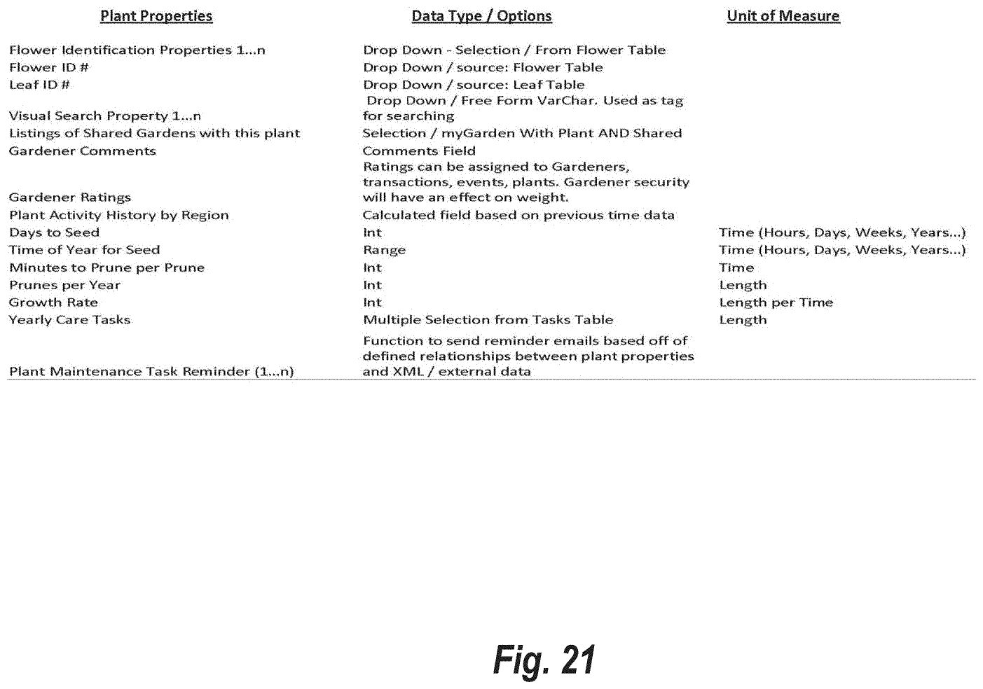

FIG. 21 shows additional specific properties of plant information contained within a specific plant record in The Plant Book, the proper name given to GWGS plant database. The Plant Book strives to obtain as much information about plants as possible. User's may request additional property fields be added through sub-process 216 as detailed above, as well as provide information to fill-in missing information. All information may be verified by an authorized user such as a professional horticulturist.

The Plant Book is a library tool that includes a comprehensive database of plants and plant information. A one-stop-shop for relevant horticultural information. In another scenario, the Plant Book is a community-driven encyclopedia (very similar to WIKIPEDIA) with all information being reviewed and validated by platform approved horticultural experts.

One of the most unique features of GWGS is the visual search. The Plant Book based visual search sub-process 202 provides the ability to identify plants in one's physical environment by scanning an image of the variety and uploading to a database which then performs image recognition to feedback relevant information. This can also be done manually. A categorization process is contemplated which relies on physical attributes of plants to help the member hierarchically shift through a relevant image database until a visual match is achieved.

The plant database is a collection of digitally stored electronic plant records. Each plant record can be associated to multiple plant properties. A plant property can be of any data type (i.e. integer, image, class, text, etc.). In this way each plant record can be tagged with information which identifies it and which can be used to associate it to other plant records.

Referring to FIGS. 13-14, each plant record will have associated visual tags. These visual tags can be in the form of images and will be used in order to conduct the plant identification search. Due to the large number of botanical properties which correspond to particular plant geometry, these geometry-based botanical properties vary from common to very uncommon. That is to say that some geometry-based botanical properties are considered common if they are shared by all or most plants in the plant world and in the same way geometry-based botanical properties are considered uncommon if they shared by only a small percentage of the plants in the plant world.

FIGS. 15-16 show leaf shapes which exhibit dentate or toothed leaf margins as well as leaf shapes which exhibit rounded leaf margins. Leaves that can grouped as similarly toothed leaf margins or similarly rounded can be grouped together and each geometry-based botanical property which is in that group can be given a similarity value corresponding to the similarity group it is contained within. As a result they can be categorized with each similarity group carrying a magnitude in relation to the total number of records in the plant database. As such the groups can be scaled from smallest to largest based on the number of plant records in common to each of the groups. Groups with the largest magnitude designate the most common features shared by plants and groups with the smallest magnitude designate the least common features plants share. Using these quantities the sequence of questions posed to the user by the dynamic search tool can be such that each question posed corresponds to the magnitude of the similarity group. The search tool will then select questions first from high magnitude similarity group and based on the response from the user can select a subsequent question from a similarity group of a lesser magnitude. This sequence can be continued until the plant record being searched for is found.

As previously mentioned, a user is able to request a plant to be added to the directory through sub-process 216. The ability for users to request a plant be added to the main directory and to be able to perform searches thereon using botanical image identifiers is a unique feature of the invention.

By using botanical image identifiers, it is possible to construct a search based on images, every plant on the planet can be defined and classified by the current botanical information available. A plant's leaves can be broken down by its characteristics. One important characteristic is the leaf margin. The leaf margin defines the geometric periphery of the leaf. From a set of known leaf margins a subtractive or exclusionary search can be performed.

Another feature of the invention is sending reminders based on local weather. The reminders (alerts) are automated and may even be tailored to user defined settings.

In yet another feature of the invention, the platform functions as a futures contract marketplace and social network combined.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blue-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. In an online platform for design, creation, maintenance, and information sharing of a garden, a method comprising:
generating a user interface for receiving from one or more users of the platform ecological, botanical, environmental and/or geographical information for the design, creation, maintenance and information sharing of a garden;
generating a database of garden knowledge using the information from the one or more users received by the user interface, the database of garden knowledge comprising a centralized database of gardening information, including garden data and garden tasks, that is accessible and shared by and between the users and that is dynamically modifiable and maintained by the users via the user interface; and
communicating and collaborating, by and between the one or more users via the user interface, to modify, maintain and share the gardening information in the centralized database.

2. The method of claim 1, wherein the centralized database of gardening information further includes at least one plant database that is dynamically modifiable and maintained by the one or more users via the user interface.

3. The method of claim 2, further comprising creating a digital representation of plants the one or more users may have in a garden, the digital representation correlating to relative physical location of plants in a garden; and wherein the at least one plant database contains the digital representation of plants.

4. The method of claim 2, further comprising performing, by the one or more users via the user interface, plant identification searches by identifying plant characteristics, such as geometry-based botanical properties, in a visual search for any plant in the plant database using a subtractive or exclusionary algorithm.

5. The method of claim 2, further comprising requesting, by the one or more users via the user interface, the addition of a new plant record into the plant database so as to enhance the plant database, sending a notification to one of the users that is authorized to approve or deny the addition of the plant record, updating the plant database with the new plant record and publishing the updated plant database to allow the one or more users to access the new plant record when the addition of the plant record is approved.

6. The method of claim 2, wherein the online platform comprises an online environment where the one or more users go to plan, create, grow and/or share gardens with one another, including selecting plants from the plants database to grow; and further comprising automatically generating a calendar of gardening tasks from the plants selected to grow, the gardening tasks including a set of garden selections, instructions, or guidelines as best practices for the one or more users to follow when planning, creating, growing and/or sharing gardens with one another.

7. The method of claim 1, wherein the communicating and collaborating by and between the users includes forming a group by and between the users for community gardening via the user interface using the centralized database of gardening information.

8. The method of claim 1, wherein the centralized database of gardening information further includes a garden maintenance and alerts database; and further comprising automatically populating the garden maintenance and alerts database with gardening tasks based on plants which the one or more users may have in their garden.

9. The method of claim 8, further comprising generating and sending to the one or more users, by the maintenance and alerts database, integrated electronic reminders regarding when to perform gardening tasks based on user defined criteria including the user's local weather, editable list of plants which currently exist in their garden or list of desired plants for their garden.

10. The method of claim 1, wherein the online platform comprises an online environment where the one or more users go to plan, create, grow and/or share gardens with one another; and further using the online environment, by the one or more users via the user interface, to post listings for the sale, trade, barter and donation of goods and services related to gardening, including plants grown in the gardens by the one or more users.

11. The method of claim 1, wherein the online platform comprises an integrated online garden community; and further comprising using the integrated online garden community, by the one or more users via the user interface, to create and maintain gardens, keep records of tasks performed including their progress at every stage of gardening, and collaborate with other users in real time including learning and trading information with other users.

12. A computer program medium including a non-transitory computer program product that aids in the design, creation, maintenance, and information sharing of a garden, and includes instructions to:
generate a user interface for receiving from one or more users of the platform ecological, botanical, environmental and/or geographical information for the design, creation, maintenance and information sharing of a garden;
generate a database of garden knowledge using the information from the one or more users received by the user interface, the database of garden knowledge comprising a centralized database of gardening information, including garden data and garden tasks, that is accessible and shared by and between the users and that is dynamically modifiable and maintained by the users via the user interface; and
communicate and collaborate, by and between the one or more users via the user interface, to modify, maintain and share the gardening information in the centralized database.

13. The computer program medium of claim 12, wherein the centralized database of gardening information further includes at least one plant database; and further comprising an instruction to dynamically modify and maintain the plant database by the one or more users via the user interface.

14. The computer program medium of claim 13, further comprising: an instruction to create a digital representation of plants the one or more users may have in a garden, the digital representation of plants being contained in the plant database and correlating to relative physical location of plants in a garden; and an instruction to perform, by the one or more users via the user interface, plant identification searches by identifying plant characteristics, such as geometry-based botanical properties, in a visual search for any plant in the plant database using a subtractive or exclusionary algorithm.

15. The computer program medium of claim 13, further comprising instructions to request, by the one or more users via the user interface, the addition of a new plant record into the plant database so as to enhance the plant database, send a notification to one of the users that is authorized to approve or deny the addition of the plant record, update the plant database with the new plant record, and publish the updated plant database to allow the one or more users to access the new plant record when the addition of the plant record is approved.

16. The computer program medium of 13, wherein the online platform comprises an online environment where the one or more users go to plan, create, grow and/or share gardens with one another, including selecting plants from the plants database to grow; and further comprising an instruction to automatically generate a calendar of gardening tasks from the plants selected to grow, the gardening tasks including a set of garden selections, instructions, or guidelines as best practices for the one or more users to follow when planning, creating, growing and/or sharing gardens with one another.

17. The computer program medium of claim 12, wherein the communicating and collaborating by and between the users includes an instruction to form a group by and between the users for community gardening via the user interface using the centralized database of gardening information; wherein the online platform comprises an integrated online garden community; and further comprising an instruction to use the integrated online garden community, by the one or more users via the user interface, to create and maintain gardens, keep records of tasks performed including their progress at every stage of gardening, and collaborate with other users in real time including learning and trading information with other users.

18. The computer program of claim 12, wherein the centralized database of gardening information further includes a garden maintenance and alerts database; and further comprising instructions to automatically populate the garden maintenance and alerts database with gardening tasks based on plants which the one or more users may have in their garden, and to generate and send to the one or more users, by the maintenance and alerts database, integrated electronic reminders regarding when to perform gardening tasks based on user defined criteria including the user's local weather, editable list of plants which currently exist in their garden or list of desired plants for their garden.

19. The computer program of claim 12, wherein the online platform comprises an online environment where the one or more users go to plan, create, grow and/or share gardens with one another; and further comprising an instruction to use the online environment, by the one or more users via the user interface, to post listings for the sale, trade, barter and donation of goods and services related to gardening, including plants grown in the gardens by the one or more users.

20. A system for the design, creation, maintenance, and information sharing of a garden, the system comprising:
a user interface for receiving from one or more users of the system ecological, botanical, environmental and/or geographical information for the design, creation, maintenance and information sharing of a garden;
a database of garden knowledge generated using the information from the one or more users received by the user interface, the database of garden knowledge comprising a centralized database of gardening information, including garden data and garden tasks, that is accessible and shared by and between the users and that is dynamically modifiable and maintained by the users via the user interface; and
one or more modules enabling communication and collaboration, by and between the one or more users via the user interface, to modify, maintain and share the gardening information in the centralized database.
